(19) United States
(12) Patent Application Publication
(10) Pub. No.: US 2010/0288014 A1
(43) Pub. Date: Nov. 18, 2010

(54) Gas sensor and method thereof

(75) Inventors: Da-Jeng Yao, Hsin Chu City (TW); Chia-Min Yang, Hsin Chu City (TW); Kea-Tiong Tang, Hsin Chu City (TW); Hsu-Chao Hao, Hsin Chu City (TW); Je-Shih Chao, Hsin Chu City (TW); Pei-Hsin Ku, Hsin Chu City (TW); Cheng-Han Li, Hsin Chu City (TW)

Correspondence Address: BACON & THOMAS, PLLC, 625 SLATERS LANE, FOURTH FLOOR, ALEXANDRIA, VA, 22314-1176, US

(73) Assignee: National Tsing Hua University, Hsin Chu (TW)

(21) Appl. No.: 12/461,400

(22) Filed: Aug. 11, 2009

(30) Foreign Application Priority Data
May 13, 2009 (TW) 098115867

(51) Int. Cl. G01N 29/02; H03B 5/30

(52) U.S. Cl. 73/24.06; 331/155

(57) ABSTRACT

A gas sensor comprises a first surface-acoustic-wave device, at least one further surface-acoustic-wave device, and a control device. The first surface-acoustic-wave device includes a piezoelectric substrate, a pair of transducers and an external circuit. The pair of transducers consists of a first transducer and a second transducer, and they are formed on two sides of the piezoelectric substrate. The first transducer is utilized to generate a surface acoustic wave on the piezoelectric substrate. The external circuit electrically connects to the pair of transducers. At least one further surface-acoustic-wave device includes at least one first surface-acoustic-device and a sensing porous thin film of which two sides are formed on the pair of the transducers. The control device is utilized to control only one external circuit to become activated at one time.

### FIELD OF THE INVENTION

The present invention relates to a sensor, and more particularly to a sensor utilizing surface-acoustic-wave array oscillating circuits to sense at least one low concentration object at the same time and method thereof.

### BACKGROUND OF THE INVENTION

Of various conventional sensors, such as metal-oxide-semiconductor sensors (MOS), conducting-polymer sensors (CPS), metal-oxide field-effect transistors (MOSFET), fluorescent odor sensors, ion-mobility spectrometry (IMS), and so on, each has its respective constraints. For example, the metal-oxide-semiconductor sensors (MOS) must be operated in a high-temperature environment, and they possess poor capability to recognize heteropolar compounds and bad selectivity; the conducting-polymer sensors (CPS) are easily perturbed by humidity. A need therefore arises to develop a sensor that has several advantages such as operating near 23° C., great sensibility, modest cost, and so on. The surface-acoustic-wave device is an appropriate choice to fulfill all these requirements.

Because the propagation characteristics of a surface-acoustic wave are easily influenced by external environmental factors, a surface-acoustic-wave device is appropriate to serve as a sensing device. FIG. 1, it shows a conventional surface-acoustic-wave device 1, which consists of a piezoelectric substrate 3 and a pair of inter-digital transducers 5. The transducers are utilized to convert variations of the external environment, such as variations of magnetic field, frequency, phase, temperature, and so on, into correlation signals. The correlation signals are then calculated to generate a corresponding result such as the species and contents of sensing objects.

A single-sensor in prior art cannot, however, measure multiple sensed objects simultaneously: the single-sensor can measure only one specific object. The domain and scope of use of a single sensor are therefore generally limited.

Another conventional transducer is an inter-digital transducer (IDT). Such an inter-digital transducer has issues of width, length, and electrode spacing specified by the material of the inter-digital transducer to create an inadequate frequency response of the device.

In addition, a conventional surface-acoustic-wave array sensor has the properties of electrical consumption and easily causing a mutual interference between sensing devices. In particular, a portable device has arranged into it a reduced-volume conventional matrix-array surface-acoustic-wave sensor, which can generate an error action due to interference between the sensing devices.

A need therefore arises to develop a novel and advanced sensor that is convenient to carry and that can sense multiple objects concurrently in a low concentration environment. Otherwise, the sensor requires advantages, such as modest cost, great sensibility and accuracy.

### SUMMARY OF THE INVENTION

In view of the foregoing, the present invention provides a discontinuous-type surface-acoustic-wave array oscillating-circuit sensor. Integrating the characteristics of a piezoelectric material, surface acoustic wave, a thin film, and external correlation circuits into the senor of the present invention enables the sensor to detect at least one object at a particular time in a low concentration environment.

The first purpose of the present invention is to provide a switching device to construct a discontinuous-type surface-acoustic-wave array oscillating circuit. Connecting the control ends of the switching device to a front end of each external circuit individually, only one sensing device is activated at one time. The power consumption of the sensing device can thus be decreased and the mutual interference between the sensing devices becomes preventable. Otherwise, utilizing a counting register to control the switching frequency and the switching amount of the switching device by monitoring the frequency of the counting register, the switching speed of the switching device is controlled. Finally, the output terminals of the external circuit are connected to a frequency counter and a calculating device to calculate the variation of each sensing device. The characteristics, such as species and quantity of sensing objects, are then obtainable.

The second purpose of the present invention is to provide a discontinuous-type surface-acoustic-wave array oscillating circuit. According to various characteristics of thin films disposed on each surface-acoustic-wave device, the sensor can sense various objects at the same time. Because one of the aforementioned sensing devices without a thin film formed thereon is utilized as a reference to create an initial value for other sensing devices, it can remove the perturbing factors in the environment.

The third purpose of the present invention is to provide an improved frequency response of a device by defining the parameters of the piezoelectric material of the transducer, such as the electrode logarithm, electrode length, electrode width, electrode spacing, and so on.

The fourth purpose of the present invention is to provide a thin film, which is formed from carbon material. Moreover, the thin film has a large surface area, and the large surface area has center holes and micro holes.

To achieve the above purposes, the present invention discloses a gas sensor. The gas sensor comprises an array of surface-acoustic-wave devices that comprises at least one surface-acoustic-wave device. The gas sensor includes a first surface-acoustic-wave device, at least one further surface-acoustic-wave device, and a control device. The first surface-acoustic-wave device comprises a piezoelectric substrate, a pair of transducers and an external circuit. The pair of transducers consists of a first transducer and a second transducer, formed on two sides of the piezoelectric sensor. The first transducer is utilized to generate surface acoustic wave on the piezoelectric substrate, and the external circuit is electrically connected to the pair of the transducers. Moreover, the first surface-acoustic-wave device is utilized to exclude interference of environmental factors. Further, at least one further surface-acoustic-wave device comprises at least one surface-acoustic-wave device and a sensing porous thin film, of which two sides are formed on the pair of the transducers of the first surface-acoustic-wave device. The control device serves as a power switch, and an output terminal of the control device connects to a front end of an external circuit to control only one external circuit in the control device to be activated at any one time. When a sensing object adheres to the sensing porous thin film, a variation of the surface-acoustic wave becomes transferred to the second transducer through the sensing porous thin film. Moreover, the variation of the surface-acoustic wave is transferred to a frequency counter, which comprises an external device. The results of the variation of the frequency of the surface-acoustic wave can be measured by the frequency counter. Quantitative and qualitative analysis of the sensing object are thus obtainable. Furthermore, one characteristic of the present invention is to utilize the control device to switch the power supply of the external circuits so as to transfer signals of the discontinuous-type surface-acoustic-wave device.

To achieve the above purposes, the present invention also discloses a method of sensing an object. The method comprises the following procedures: (a) providing a first surface-acoustic-wave device and at least one further surface-acoustic-wave device, wherein the process thereof includes (i) providing the first surface-acoustic-wave device that includes a piezoelectric substrate and a pair of transducers formed on the piezoelectric substrate, wherein the pair of the transducers consists of a first transducer and a second transducer, and (ii) providing at least one further surface-acoustic-wave device that is formed from a porous thin film on the pair of transducers of the first surface-acoustic-wave device; (b) applying a voltage to the first transducer with an external circuit, wherein the first transducer is utilized to convert the electrical energy to the mechanical energy and to generate surface-acoustic wave on the piezoelectric substrate; (c) controlling only one of the external circuit to output signal at one time by utilizing a control device, wherein an output terminal of the control device is connected to a front end of the external circuit; (d) measuring variance of the surface-acoustic wave transferred by the second transducer; and (e) utilizing an external device to receive signal of electrical energy transferred by the second transducer to calculate information from the thin film.

One advantage of the present invention is to provide a gas sensor, which has various characteristics of a thin film; this thin film is disposed on each surface-acoustic-wave device. The gas sensor can then sense various objects in a low concentration environment at the same time. Upon utilizing a discontinuous-type array, especially, the mutual interference of the devices on a small-volume apparatus becomes preventable. The sensor thereby acquires several advantages, such as small volume, modest cost, small loss of energy, a satisfactory frequency response of the device, and so on.

A detailed description is given in the following embodiments and with reference to the accompanying drawings and claims.

### BRIEF DESCRIPTION OF THE DRAWINGS

FIG. 1 is a diagram of a conventional surface-acoustic-wave device.

FIG. 2 is a diagram of an inter-digital transducer.

FIG. 3 is a diagram of a discontinuous-type surface-acoustic-wave array oscillating-circuit sensor.

FIG. 4 is a diagram of a surface-acoustic-wave oscillating circuit.

FIG. 5 is a flow chart of the procedures to manufacture the surface-acoustic-wave device.

FIG. 6 is a testing statistical chart of flowing amine gas into a discontinuous-type surface-acoustic-wave array oscillating-circuit sensor four times.

FIG. 7 is a statistical bar chart showing sensing by thin films of seven kinds of gases of five kinds.

FIG. 8 is a diagram of a measurement result of a PNVP film to variable consistencies of alcohol.

FIG. 9 is a diagram of parameters of the normalizing method.

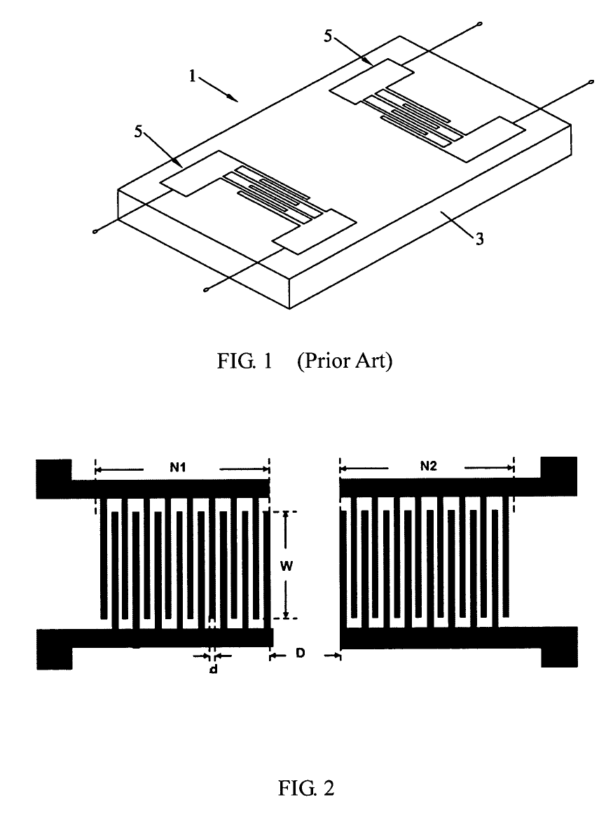

### DETAILED DESCRIPTION OF THE PREFERRED EMBODIMENT

The invention is hereinafter described in greater detail with preferred embodiments of the invention and accompanying illustrations. Nevertheless, it should be recognized that the preferred embodiments of the invention are provided not to limit the invention but to illustrate it. The present invention is implementable in not only the preferred embodiments herein mentioned, but also diverse other embodiments, besides those explicitly described. Further, the scope of the present invention is expressly not limited to any particular embodiments except what are specified in the appended Claims.

One preferred embodiment of the present invention discloses a discontinuous-type surface-acoustic-wave oscillating-circuit array sensor to utilize various characteristics of thin films disposed on each surface-acoustic-wave device to sense various low concentration gases at the same time. Moreover, the sensor can be set into a portable device for convenient carrying and for sensing gas with the varied demands.

First of all, several parameters of an inter-digital transducer (IDT) of this embodiment of the present invention are described below. As used here, these parameters are utilized only to explain this embodiment of the present invention, and not to limit the appended claims of the present invention. FIG. 2 shows a diagram of the inter-digital transducer and the parameters thereof. Symbol W denotes a width of an electrode of a transducer, also called a width of the IDT pattern. Symbol D denotes a distance between two adjacent transducers, and also called the inter-space between the IDTs. Moreover, symbol d denotes a width of the inter-electrode of the transducer. Symbols N1 and N2 denote lengths of two adjacent transducers, respectively. In certain embodiments, the preferred width, W of an inter-digital transducer pattern is 3800 μm, the preferred width, d of the inter-electrode of the transducer is 10 μm, and the preferred inter-space, D between the IDT is 4000 μm. The preferred N1 and N2 comprise thirty finger-pairs of inter-digital transducers, respectively, and the width and inter-space of the electrode of the inter-digital transducer are a quarter wavelength. The aforementioned parameters are preferred parameters to obtain an optimal frequency response of the inventive device.

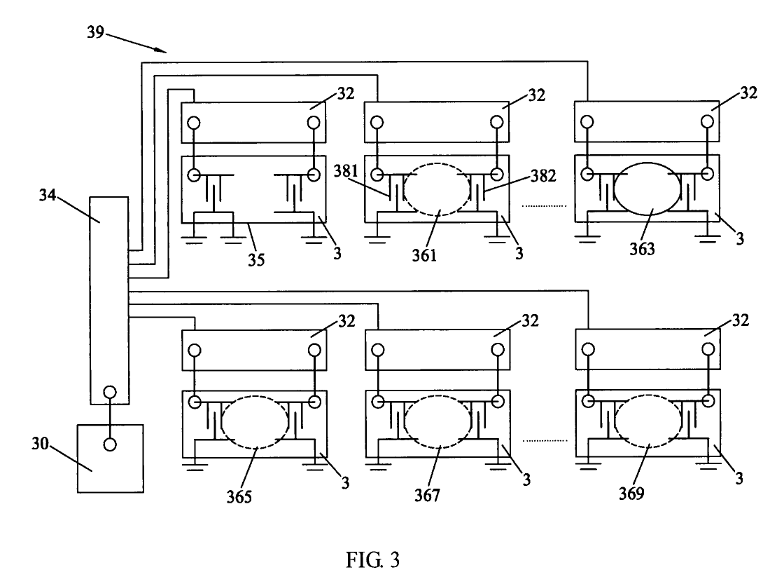

FIG. 3 shows the preferred embodiment of the present invention, which comprises a surface-acoustic-wave circuit array 39. The surface-acoustic-wave circuit array 39 comprises one or more surface-acoustic-wave device. The surface-acoustic-wave device comprises a piezoelectric substrate 3 and a pair of transducers, which consist of a first transducer 381 and a second transducer 382, formed on two sides of the piezoelectric substrate 3. Moreover, sensing thin films 361˜369 with a porous nature, for example the sensing thin film 361, form on two sides of the pair of transducers. As shown, a surface-acoustic-wave device 35 without a sensing thin film formed thereon is utilized to serve as a reference oblique inter-digital transducer to create an initial value. Then, variations of a physical quantity, such as a variation of phase velocity or wave propagation, of the other surface-acoustic-wave devices can be compared with surface-acoustic-wave device 35 to enable excluding environmental perturbing factors. Furthermore, the first transducer 381 is utilized to convert electrical energy to mechanical energy and to generate a surface-acoustic wave on the piezoelectric substrate 3. The second transducer 382 is utilized to convert mechanical energy to electrical energy. When the surface-acoustic wave is received by the second transducer 382, it converts the surface-acoustic wave to an electrical signal, which is transferred by a transmission line to an external device (not shown).

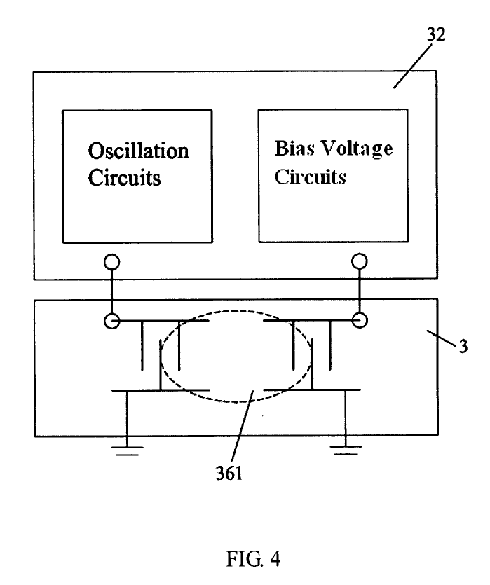

FIG. 4 shows an external circuit 32, which includes bias voltage circuits and oscillation circuits. The bias voltage circuits and the oscillation circuits are electrically connected to the pair of transducers. A bias voltage generated by the bias voltage circuits is applied to the first transducer 381 such that a surface-acoustic wave is generated by the first transducer 381. Moreover, in this preferred embodiment, the sensor of the present invention comprises a control device 34 to serve as a power switch, which comprises a multiplexer or a switch, to provide functions of data distribution or data switching. Further, output terminals of control device 34 are disposed on the front end of these external circuits 32 to control only one external circuit 32 activated at one time. When a sensing subject is adhered to the sensing porous thin film 361 (as an example), a variation of a physical quantity of the surface-acoustic wave is transferred by the sensing porous thin film 361 to the second transducer 382. The physical quantity variation of the surface-acoustic wave is transferred by the second transducer 382 to a counting register or a universal counter (not shown) to read the value of frequency. The value of frequency is then recorded with a computer (not shown), and qualitative and qualitative analysis of the sensing object are obtained.

In this embodiment, the piezoelectric substrate 3 is fabricated from 128° YX—LiNbO₃, but not limited. In another certain embodiments, the piezoelectric substrate 3 is fabricated from selecting one or more piezoelectric materials including aluminum nitride (AlN), gallium arsenide (GaAS), zinc oxide (ZnO), lead zirconate titanate (PZT), or combinations thereof. In this embodiment, a center frequency of the device is about 99.8 MHz.

Another embodiment of the present invention describes a variation of the frequency of a surface-acoustic-wave device of the sensor of the present invention. An adhered thin film 361 having selectivity and uniqueness is disposed on a sensing region of a surface-acoustic-wave device. When the sensor is exposed to an environment with a target sensing object, an input electrical signal is converted to mechanical wave with a first transducer 381. The mechanical wave is transferred in a delay line. The excited surface wave is physically or chemically adhered to the porous thin film 361 in the sensing region such that a variation of the wave speed is produced by a variation of the mass in the sensing region. Moreover, a second transducer 382 is utilized to convert a signal of mechanical energy to an electrical signal output, and then variations of physical quantity, such as a variation of a center frequency, phase or loss of energy, can be measured with an instrument. The variation of frequency is caused by the specified molecules of the adhered gaseous sample. When a variation of the drift velocity of the wave is received by the second transducer 382, the variation becomes converted to an electrical signal, which is in turn transferred to a universal counter (not shown), and the value of the frequency is shown on a screen of the counter. Moreover, when a reading speed of the universal counter is set as 1 (reading/s), the resolution of the counter can attain 0.01 Hz. A small variance of frequency thus becomes measurable. Further, the electrical signal is transferred to a calculating device (not shown) for qualitative and quantitative analysis. From the foregoing, the sensor of the present invention can be placed in a low concentration environment for sensing.

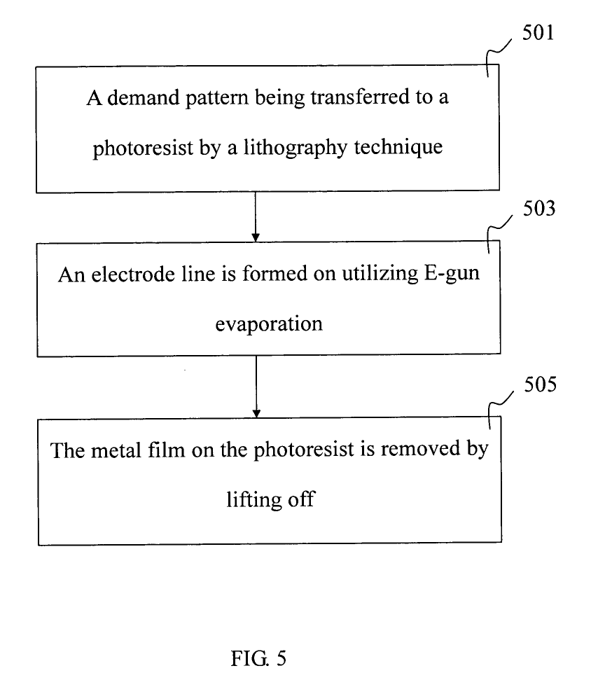

FIG. 5 shows how the sensor of the present invention is manufactured by the procedures shown therein. The procedures comprise three steps. The step 501 comprises a demand pattern being transferred to a photoresist by a lithography technique. In certain embodiment, the pattern is transferred to the photoresist on exposure to a mercury lamp; the duration of exposure is about 15 s. During exposure, alignment of the inter-electrode is important. Further, a developing process is executed on utilizing a mixture of a developing solution (AZ400K) and a deionized water (DI water); the mixing ratio of the developing solution and deionized water is 1:5. The duration of the development is about 80 s. Further, the step 503 comprises that an electrode line is formed on utilizing E-gun evaporation. In a certain embodiment, the material of deposition is selected to be gold (Au). As the adhesion ability of gold is poor, a chromium layer is first deposited of thickness about 20 nm as an adhesive layer; a gold layer is then deposited on the chromium layer of thickness about 100 nm as the electrode line. The step 505 comprises that the metal thin film on the photoresist is removed by lifting off. In a certain embodiment, the wafer is soaked in a solution of propanone so that the metal thin film becomes removable. Moreover, the metal film that is not easily lifted is removed by ultrasonic vibration. When the fabrication of the sensing wafer is finished, these sensing porous thin films 361˜369 are deposited to enhance the sensitivity of the sensing device and selectivity of the sensing gases. The porous material is deposited directly on the sensing wafer by spin coating. Further, the sensing wafer is electrically connected to the external circuit 32, and a surface-acoustic-wave device having a sensing porous thin film is fabricated.

Materials of the aforementioned porous thin film are selected from polymeric materials or nano-porous materials, but are not limited thereto. The abovementioned polymeric materials comprise poly(N-vinylpyrrolidone) (PNVP), poly(4-vinylphenol) (P4VP), polystyrene (PS), polyvinyl acetate (PVAc), polystyrene-co-maleic-anhydride (PSMA), polyethylene glycols (PEG), polysulfone (PSu), or derivatives thereof, but are not limited thereto. Moreover, the thickness of the final finished thin film is about 0.5˜10 μm.

From the foregoing, the sensor of the present invention is utilized for the control device 34 to switch the power of the external circuit 32 so as to control only one of the external circuits 32 to generate oscillation as output. When one external circuit 32 is activated, the others external circuits 32 do not act, thereby the output signal of the surface-acoustic-wave array device is discontinuous. Mutual interference of all surface-acoustic-wave devices acting at the same time thus becomes prevented. Because only one external circuit 32 acting, the maximum value of the current is only that of the counting register 30 and one surface-acoustic-wave oscillating circuits so that the power consumption is small. Moreover, various porous thin films 361˜369 are disposed on the surface-acoustic-wave array device to sense various sensed objects at the same time. Furthermore, the characteristics of the surface-acoustic-wave device comprise great sensitivity to perturbation by the external environment. The sensor of the present invention can therefore sense concurrently various sensed objects in a low concentration environment, and subject these sensed objects for qualitative or quantitative analysis.

Further, a measuring method of the present invention to utilize the discontinuous-type surface-acoustic-wave array sensor aforementioned is disclosed as follows.

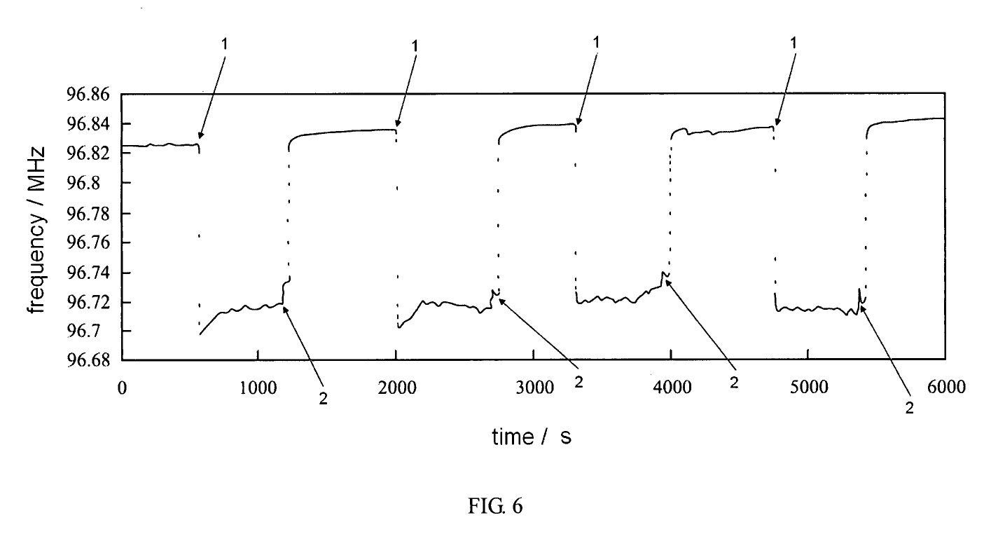

In one embodiment of the present invention, the discontinuous-type surface-acoustic-wave array oscillating-circuit sensor is placed in a test chamber. Then, ammonia vapour is generated with a gas generator for testing gases. The surface of the surface-acoustic-wave sensor is covered with a porous poly(N-vinylpyrrolidone) (PNVP) thin film for measurement. FIG. 6 shows a result on repeating cycles of ammonia four times. Arrow 1 denotes the time of addition of ammonia, and the arrow 2 denotes the time of addition of air. There are four times cycles. As shown in FIG. 6, the frequency drift tends to decrease. The stability and repeatability of the circuit combined with the surface-acoustic-wave device can thus attain an acceptable level. Moreover, depending on the various sensed gases, the trend of frequency drift and amount of frequency drift would vary.

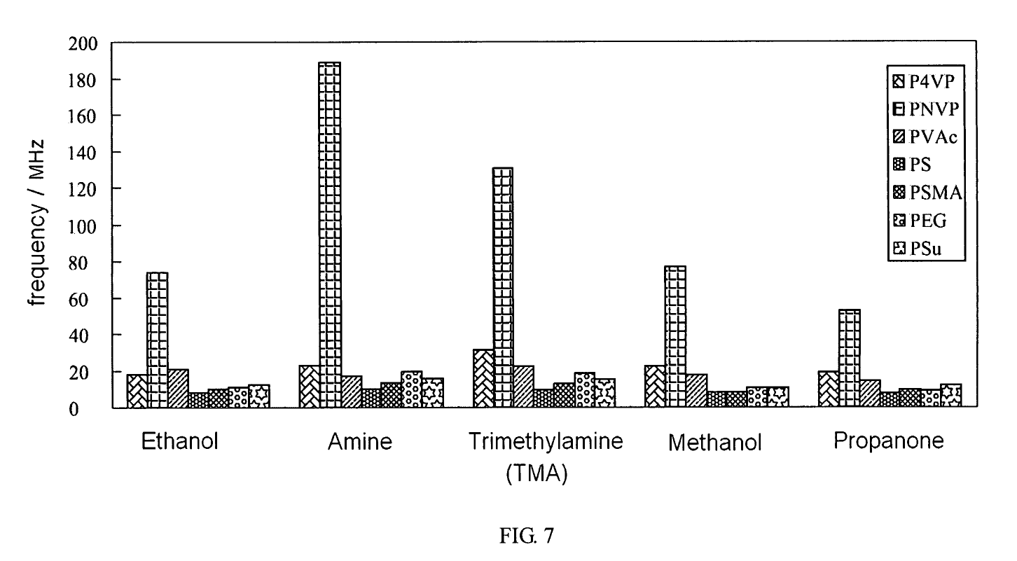

In another embodiment of the present invention, the discontinuous-type surface-acoustic-wave array oscillating-circuit sensor is placed in an environment containing five varied gases for testing. In this embodiment, the materials of the porous thin film are polymeric materials. Referring to FIG. 7, this diagram describes the statistics of response of the five varied gases to seven varied sensing thin films. The seven sensing thin films comprise poly(4-vinylphenol) (P4VP), poly(N-vinylpyrrolidone) (PNVP), polyvinyl acetate (PVAc), polystyrene (PS), polystyrene-co-maleic-anhydride (PSMA), polyethylene glycols (PEG), and polysulfone (PSu); and the gases comprise ethanol, amine, trimethylamine (TMA), methanol and propanone. In the measurement of the discontinuous-type surface-acoustic-wave array oscillating circuit of the present invention, the difference of frequency Δf between of the various surface-acoustic-wave devices has a large difference at each repeated experiment. Referring to FIG. 7, the device having a large initial frequency is more sensitive, and the value of Δf increases. Therefore, in the embodiment of the present invention, the analysis of data is conducted by a method of normalization, which is a method utilizing proportion for calculating, according to the equation shown below:

$$\frac{Δ f}{{f}_{0} - {f}_{p}} = \frac{{f}_{m} - {f}_{c}}{{f}_{0} - {f}_{p}}$$

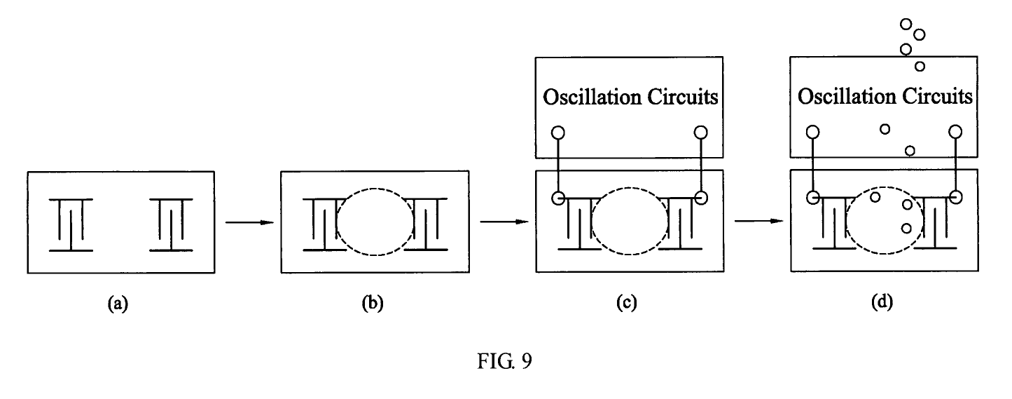

FIG. 9 helps to understand each parameters of the aforementioned equation. Symbol f₀ denotes an initial frequency of the surface-acoustic-wave wafer which has no coated polymeric material thin film, as shown in FIG. 9(a); symbol fₚ denotes a frequency of the surface-acoustic-wave wafer that is coated with a polymeric material thin film, as shown in FIG. 9(b); symbol f_{c} denotes a frequency of the surface-acoustic-wave wafer coated with a thin film of a polymeric material on the oscillating circuits, as shown in FIG. 9(c); and symbol fₘ denotes the frequency of the surface-acoustic-wave wafer combined with the oscillating circuits after sensing gases, as shown in FIG. 9(d). Every sensing wafer that is coated with various thin films can be observed objectively and consistently. Moreover, the response of the PNVP film is several times as large as that of other polymeric materials, as shown in FIG. 7. The sensing results evidently vary because of the characteristics of the various films. When the sensitivity is greater (Δf is larger), the noise (standard deviation) is also larger. Besides, in this embodiment, it is clearly understood that the sensor of the present invention can sense at least one sensed subject at the same time.

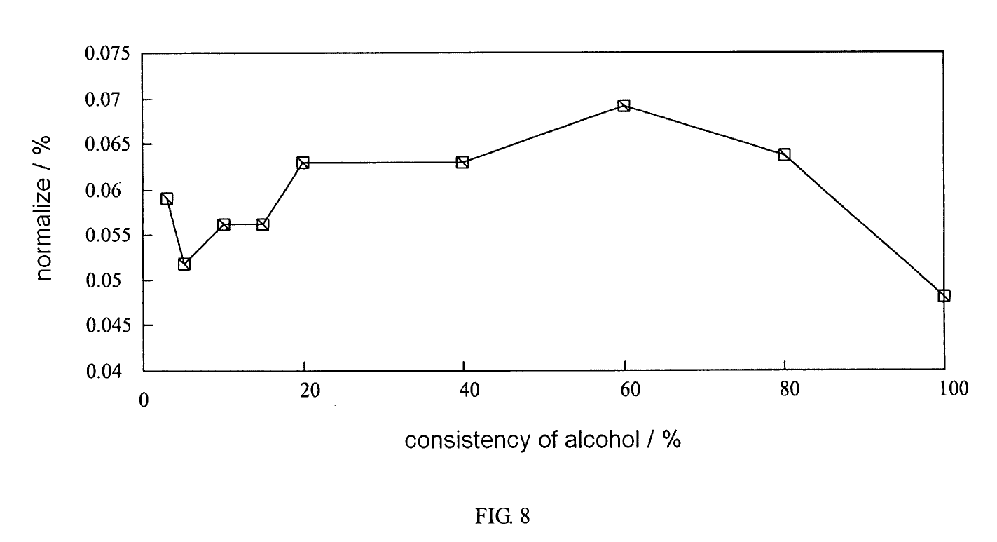

In another embodiment of the present invention, the discontinuous-type surface-acoustic-wave array oscillating-circuit sensor is placed in various concentration of a gas for testing. Referring to FIG. 8, the material of the sensing thin film of this embodiment is poly(N-vinylpyrrolidone) (PNVP), and the gas of this experiment is alcohol. The proportions of the alcohol vary between 0% and 100%, and are concocted with the complementary proportions of water. FIG. 8 shows the results of this embodiment, a relation between the variation of the sensed frequency and the varied concentration of the alcohol is readily evident. Further, in this embodiment, it is clearly understood that the sensor of the present invention can sense gases in varied concentrations. Moreover, the sensor of the present invention can be disposed on a portable device, such as a breath tester for ethanol.

Although the embodiments of the present invention disclosed herein are at present considered to be preferred embodiments, various changes and modifications can be made without departing from the spirit and scope of the present invention. The scope of the invention is indicated in the appended claims, and all modification that come within the meaning and range of equivalents are intended to be embraced therein.

What is claimed is:

1. A gas sensor, comprising:
a first surface-acoustic-wave device which includes a piezoelectric substrate, a pair of transducers and an external circuit, wherein said pair of transducers comprises a first transducer and a second transducer which are formed on two sides of said piezoelectric substrate, and said first transducer is utilized to generate a surface-acoustic wave on said piezoelectric substrate, wherein said external circuit electrically connects to said pair of the transducers;
at least one further surface-acoustic-wave device which includes at least one said first surface-acoustic-wave device and a sensing porous thin film which is formed on two sides of said pair of said transducers; and
a control device to serve as a power switch, and an output terminal of said control device disposed on a front end of said external circuit to control only one of said external circuit to be activated at one time;
wherein a sensing object adheres to the porous thin film, and a variance of said surface-acoustic wave is transferred to said second transducer by said porous thin film to receive and to calculate said variation of said surface acoustic wave.

2. The gas sensor as claimed in claim 1, further comprising:
a counting register, which is utilized to control a switching frequency and a switching amount of said control device.

3. The gas sensor as claimed in claim 1, wherein said pair of transducers comprises an inter-digital transducer (IDT) respectively, and width and space between all electrodes of said inter-digital transducer are the same.

4. The gas sensor as claimed in claim 3, wherein said width and space between said electrodes of said inter-digital transducer is a quarter wavelength.

5. The gas sensor as claimed in claim 1, wherein material of said pair of transducers comprises gold.

6. The gas sensor as claimed in claim 1, wherein thickness of said porous sensing thin film is about 0.5˜10 μm.

7. The gas sensor as claimed in claim 1, wherein material of said porous sensing thin film comprises a polymeric material, or a nano-porous material.

8. The gas sensor as claimed in claim 7, wherein materials of said polymeric material is selected from poly(N-vinylpyrrolidone) (PNVP), poly(4-vinylphenol) (P4VP), polystyrene (PS), polyvinyl acetate (PVAc), polystyrene-co-maleic-anhydride (PSMA), polyethylene glycols (PEG), polysulfone (PSu), or combination thereof.

9. The gas sensor as claimed in claim 1, wherein said external circuit comprises bias voltage circuits and oscillation circuits.

10. The gas sensor as claimed in claim 1, wherein said variance of said surface acoustic wave is selected from variations of center frequency, phase, velocity, or loss of energy.

11. The gas sensor as claimed in claim 1, wherein said control device comprises a multiplexer or a switch.

12. The gas sensor as claimed in claim 1, wherein said first transducer is utilized to convert electrical energy to mechanical energy; and aid second transducer is utilized to convert mechanical energy to electrical energy, and vice versa.

13. The gas sensor as claimed in claim 1, wherein material of piezoelectric substrate is selected from 128°YX—LiNbO₃, aluminum nitride (AlN), gallium arsenide (GaAs), zinc oxide (ZnO), lead zirconate titanate (PZT), or combination thereof.

14. A method of sensing an object, and procedures of said method comprising:
providing a first surface-acoustic-wave device and at least one further surface-acoustic-wave device, wherein said first surface-acoustic-wave device is provided first, and said first surface-acoustic-wave device comprises a piezoelectric substrate, a pair of transducers formed on said piezoelectric substrate, and said pair of transducers consists of a first transducer and a second transducer, then, said at least one further surface-acoustic-wave device is provided, and said at least one further surface-acoustic-wave device including at least one said first surface-acoustic-wave device having a porous thin film, and two sides of the porous thin film is formed on said pair of transducers;
applying a voltage from an external circuit to said first transducer, wherein said first transducer is utilized to convert electrical energy to mechanical energy and to generate a surface-acoustic wave on said piezoelectric substrate;
controlling only one of said external circuit to output a signal at one time by utilizing a control device, wherein an output terminal of said control device is connected to a front end of said external circuit;
measuring variations of said surface acoustic wave transferred by said second transducer; and
utilizing an external device to receive said electrical energy transferred by said second transducer to calculate an information from said sensing thin film.

15. The method as claimed in claim 14, further comprising:
providing a counting register, which is utilized to control a switching frequency and a switching amount of said control device.

16. The method as claimed in claim 14, wherein said pair of transducers comprises an inter-digital transducer, and width and space between all electrodes of said inter-digital transducer are the same.

17. The method as claimed in claim 16, wherein said width and space between said electrodes of said inter-digital transducer is a quarter wavelength.

18. The method as claimed in claim 14, wherein material of said porous sensing thin film comprises a polymeric material, or a nano-porous material.

19. The method as claimed in claim 18, wherein materials of said polymeric material is selected from poly(N-vinylpyrrolidone) (PNVP), poly(4-vinylphenol) (P4VP), polystyrene (PS), polyvinyl acetate (PVAc), polystyrene-co-maleic-anhydride (PSMA), polyethylene glycols (PEG), polysulfone (PSu), or combination thereof.

20. The method as claimed in claim 14, wherein said variance of surface acoustic wave is selected from variations of center frequency, phase, velocity, or loss of energy.
